(19) United States
(12) Patent Application Publication
(10) Pub. No.: US 2002/0171417 A1
(43) Pub. Date: Nov. 21, 2002

(54) Angle detector with magnetoresistive sensor elements

(75) Inventor: Dieter Schodlbauer, Munchen (DE)

Correspondence Address: SENNIGER POWERS LEAVITT AND ROEDEL, ONE METROPOLITAN SQUARE, 16TH FLOOR, ST LOUIS, MO, 63102, US

(73) Assignee: Ruf Electronics GmbH

(21) Appl. No.: 10/152,157

(22) Filed: May 21, 2002

(30) Foreign Application Priority Data
May 21, 2001 (DE) 10124608.0
Aug. 24, 2001 (DE) 10140710.6

(51) Int. Cl. G01B 7/30; G01R 33/09

(52) U.S. Cl. 324/207.21; 324/207.25

(57) ABSTRACT

The angle detector for measuring an angle of rotation contains a first sensor having a first angle of rotation measurement range and a second sensor having a larger measurement range. The first sensor is highly accurate and generates a quite linear output signal, while second sensor is less accurate and, in particular, generates a less linear output signal. The second sensor here supplies an auxiliary signal, which is used only to determine the period of its output signal in which first sensor is currently located. The first sensor is preferably a magnetoresistive rotary field sensor of the anisotropic magnetoresistive (AMR) type, while the second sensor relies on the giant magnetoresistive (GMR) effect.

### BACKGROUND OF THE INVENTION

The invention pertains to an angle detector with two sensors and, in particular, to an angle detector with two magnetoresistive sensor elements.

DE 195 06 938 A1 discloses measuring the rotational position of rotatable components such as a shaft, using two mutually mechanically coupled sensors. The mechanical coupling is accomplished by way of gearwheels, where the number of teeth of the two gearwheels associated with the two sensors differs, for instance, by one. Both sensors here emit a periodic individual signal. Optical, magnetic, capacitive, inductive or resistive sensors can be used as sensors. The difference of the measured values of the two sensors, multiplied by the respective number of teeth, is standardized to the periodicity of the sensors, and the measured angle is determined in an additional difference formation and it is checked whether this angle is negative, in which case the full angular period is then added on.

DE 196 32 656 A1 describes a method and a device for noncontact detection of position or rotational position of an object having two parallel tracks with magnetized increments, where the number of increments per track is different, preferably by the number 1. Assigned to each track is a sensor which emits a sinusoidal and a cosinusoidal output signal as a function of the relative position between the sensor and the respective increment of the track. The phase difference of the angular values of the sinusoidal signals of the two tracks yields a linear signal which, however, is sectionally positive or negative. If this signal is free, then a constant value of 2p is added to the difference signal.

DE 198 49 554 C1 uses two sensors, of which one is only to determine the period number and add it to the current output signal of the other sensor. The mechanical coupling of two sensors to expand the measurement range is also known from EP 0 386 334 and DE 197 47 753 C1.

An essential problem of the above-cited angle detectors is that either the measuring accuracy of the system is worsened by the necessary mechanical coupling of the individual sensors (DE 195 06 938 A1 and DE 198 49 554 C1) or, for a high-resolution sensing of magnetic scales, often the only sensors available in practice are those which are too inaccurate for demanding applications (DE 196 32 656 A1).

For magnetoresistive rotary field sensors which rely, for instance, on an anisotropic magnetoresistive (AMR) effect or a giant magnetoresistive (GMR) effect, the field-direction sensitivity in the plane of the sensor element is exploited by recording the tangential component of the magnetic field (cf., for instance, the Elsevier publication, Sensors and Actuators A 91 2001; also C.P.O. Treutler, “Magnetic sensors for automotive applications”). As control magnets, it is common to use block magnets or diametrically magnetized disk magnets that are seated rotatably with respect to the sensor element and thus create a magnetic field of variable direction at the measuring site. Unfortunately, the measuring accuracy of a conventional AMR angle sensor is not available over an extended measurement range and a conventional GMR angle sensor provides unacceptable measuring accuracy.

### SUMMARY OF THE INVENTION

The invention meets the above needs and overcomes the deficiencies of the prior art by providing an angle detector, at lower expense, with two sensors for accurate measurement over an angular range that is greater than the measurement angle range of one of the sensors.

The fundamental principle of the invention is to use an accurate sensor (e.g., an AMR sensor with a limited measurement range (180°) and a second, less accurate sensor (e.g., a GMR sensor) with a larger measurement range (360°), with the second sensor serving only to determine the period of the first sensor.

In principle then, the first sensor generates an ambiguous measurement signal, while the second sensor generates an unambiguous measurement signal when the complete measurement range of 360° or more is passed through. In practice, the second sensor will therefore be less accurate than the first. It is also possible in principle, however, for both sensors to operate with roughly the same measuring accuracy.

For magnetoresistive rotary field sensors which rely, for instance, on the AMR effect or the GMR effect, the field-direction sensitivity in the plane of the sensor element is exploited by recording the tangential component of the magnetic field. As control magnets, it is common to use block magnets or diametrically magnetized disk magnets that are seated rotatably with respect to the sensor element and thus create a magnetic field of variable direction at the measuring site. It is a characteristic of the AMR effect that in this respect only the orientation of the magnetic field, but not its sign, is recognized. As a consequence, the output signal of the AMR angle sensor has a period of 180° without additional auxiliary devices, i.e., there is unambiguous measurement only over half a rotation of the control magnet. In contrast, it is possible to achieve a signal period over a full rotation with special GMR angle sensors. In comparison to a rotary field probe based on AMR technology, of course, a poorer measuring accuracy must also be accepted according to the current state of the art. With the present invention, however, the measuring accuracy of an AMR angle sensor is available over an extended measurement range, and thus, in particular, over the full 360°.

According to one embodiment of the invention, the first sensor is an AMR angle sensor and the second one a GMR angle sensor. Considered on its own, the second sensor already represents an angle sensor for 360°. Comparatively, however, only very low demands are placed on its measuring accuracy. The second angle sensor can be implemented with a wide variety of technologies. For instance, a potentiometric resistive layer in the form of a circular strip that extends nearly over an entire revolution and supplies sufficient angle information via a sliding pickup is conceivable. Preferably, however, the second angle sensor is likewise a field-direction probe operating in a noncontacting manner, so that the permanent magnet in use can drive both sensors. Thus, the second angle sensor is, for example, the aforementioned GMR sensor.

Even if in the embodiment below the AMR sensor, in a variant without a gear assembly, has only two periods in a 360° measurement range, it should be emphasized that the principle of the invention can be extended to a period number greater than 2 by, for instance, providing the AMR sensor with a step-up gear assembly. The advantage of such an arrangement is an increased resolution for the useful signal. If the gears, for instance, have a transmission ratio of 1:2, then the accurate sensor (AMR sensor) runs through four periods of its output signal while the other sensor passes through only one period.

Alternatively the invention may comprise various other embodiments. Other objects and advantages will become apparent to those skilled in the art from the detailed description herein read in conjunction with the drawings attached with.

Below the invention will be explained in greater detail on the basis of an embodiment in conjunction with the drawings.

### BRIEF DESCRIPTION OF THE DRAWINGS

FIG. 1, a schematic sketch of the sensor according to the invention;

FIG. 2, the phase angle of the two sensors as a function of the mechanical angle of rotation in degrees.

FIG. 3, a diagram of the output signal of the entire angle sensor as a function of the mechanical angle of rotation, also showing the “auxiliary signal” of the second sensor.

Corresponding reference characters indicate corresponding parts throughout the drawings.

### DETAILED DESCRIPTION OF THE INVENTION

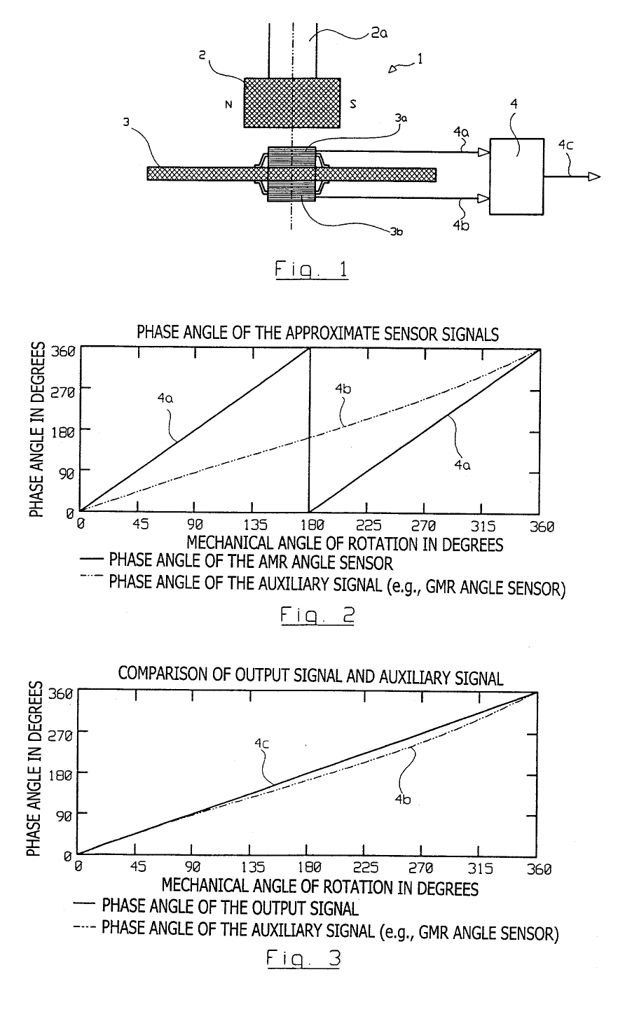

Reference will be made first of all to FIG. 1. Angle sensor 1 has a permanent magnet 2 with north pole N and south pole S and which is connected to rotatable component or object, such as shaft 2a. Opposing magnet 2, a sensor board 3 is arranged such that its face is perpendicular to the central axis of shaft 2a and points towards magnet 2. First sensor 3a, and second sensor 3b are placed on each side of sensor board 3. The position of the two sensors 3a, 3b is selected such that the center of each is aligned with the axis of rotation of shaft 2a.

First sensor 3a is a highly accurate sensor, for instance, an AMR sensor with an output signal having a first period, here a period of 180°. Compared to it, second sensor 3b is a less accurate sensor, for instance, a GMR sensor, whose output signal has a second period, here 360°, which is thus greater and specifically, an integer multiple of the period of first sensor 3a.

Both sensors 3a and 3b are connected to an evaluation electronics unit 4. The evaluation unit 4 includes two inputs 4a and 4b and one output 4c.

FIG. 2 shows a diagram of the output signals of the two sensors. The solid line is the output of first sensor 3a appearing at input 4a, represented here as strictly linear and highly precise and having a period of 180°. The second signal, represented by a broken line, is the signal of sensor 3b at input 4b, which is comparatively less accurate and, in fact, is essentially monotonically increasing but has a distinct nonlinearlity. To compensate for that, however, it extends over the entire measurement range of 360°. On the basis of this signal it is possible, even with large inaccuracies, to determine whether the output signal of first sensor 3a is in the first period, 0-180°, or the second period, 180-360°. To this end, it is possible, for instance, for the output signal of second sensor 3b to be compared to a preset limit value, by running it, for example, through a threshold switch. If the signal is greater than the set threshold value, then the value 180° is added to the output signal of first sensor 3a. To maintain accuracy even in the boundary region near 180°, the signal of first sensor 3a is also evaluated for the decision as to whether 180° is to be added or not. Here the numerical value n×180° is added to the output signal of first sensor 3a in a first step and the result is compared to the standardized signal of second sensor 3b for the same value range. In case of too great a deviation, the integer value n is then corrected appropriately in a second step. Thereafter, a simple comparator that determines whether the output signal of the second sensor is greater than 180°+x. In this case, 180° is always added to the output signal of first sensor 3a.

FIG. 3 shows the output signal at output 4c as a solid line and, in comparison to it, the less accurate, nonlinear output signal of second sensor 3b, here labeled “auxiliary signal.” The gain in measurement accuracy is clearly recognizable.

When introducing elements of the present invention or the embodiments thereof, the articles “a,” “an,” “the,” and “said” are intended to mean that there are one or more of the elements. The terms “comprising,” “including,” and “having” are intended to be inclusive and mean that there may be additional elements other than the listed elements.

In view of the above, it will be seen that the several objects of the invention are achieved and other advantageous results attained.

As various changes could be made in the above constructions and methods without departing from the scope of the invention, it is intended that all matter contained in the above description and shown in the accompanying drawings shall be interpreted as illustrative and not in a limiting sense.

What is claimed is:

1. Angle detector comprising first and second sensors, each generating a periodic output, wherein the output signals of the sensors have a different number of periods in the measurement range, wherein the first sensor is a highly accurate sensor that generates a larger number of periods in the measurement range than the second sensor, wherein the second sensor is less accurate than the first sensor and generates a less accurate signal with only one period in the measurement range and wherein the output signal of the second sensor is evaluated only to determine the instantaneous period number of the first sensor.

2. Angle detector according to claim 1, wherein the first sensor is a magnetoresistive rotary field sensor based on the effect of anisotropic magnetoresistive elements and, by evaluating the field-direction sensitivity in the plane, has a periodicity of 180°.

3. Angle detector according to claim 2, wherein the second sensor is a magnetoresistive rotary field sensor that is based on the giant magnetoresistive effect and has a measurement range of 360°.

4. Angle detector according to claim 1, wherein at least one of the sensors is coupled by means of a gearwheel to a component, the angular position of which is to be measured, wherein the gearwheel has a transmission ratio selected such that the two sensors are rotated at a different transmission ratio.

5. Angle detector according to claim 1 further comprising a control magnet connected to a component, the angular position of which is to be measured, wherein the control magnet generates a magnetic field that is of a variable direction relative to at least one of the sensors as a function of the rotational position.

6. Angle detector according to claim 1, wherein both sensors are mounted on a shared board such that their centers are each aligned with the axis of rotation of a component, the angular position of which is to be measured, and wherein the axis of rotation of the component is perpendicular to the board.

7. An angle detector for determining rotational position of a rotatable component, said angle detector comprising:
a first sensor for sensing the rotational position of the component and for generating a first measurement signal, said first measurement signal having a plurality of periods corresponding to one complete rotation of the component;
a second sensor for sensing the rotational position of the component and for generating a second measurement signal, said second measurement signal having one period corresponding to one complete rotation of the component; and
an electronic evaluation unit electrically connected to said first and second sensors for distinguishing the periods of the first measurement signal as a function of the second measurement signal.

8. The angle detector of claim 7, further comprising a sensor board for mounting said first and second sensors such that their centers are each aligned with the axis of the rotatable component, and wherein said sensor board is situated substantially perpendicular to the central axis of the rotatable component.

9. The angle detector of claim 7, wherein the first sensor is an anisotropic magnetoresistive (AMR) sensor and wherein the first measurement signal generated by the AMR sensor has a periodicity of approximately 180 degrees.

10. The angle detector of claim 7, wherein the first measurement signal has two periods in a measurement range of 360 degrees.

11. The angle detector of claim 7, wherein the second sensor is a giant magnetoresistive (GMR) sensor and wherein the second measurement signal generated by the GMR sensor has a periodicity of 360 degrees.

12. The angle detector of claim 7, wherein the second measurement signal has one period in a measurement range of 360 degrees.

13. The angle detector of claim 7, wherein the first sensor more accurately senses the rotational position of said rotatable component than the second sensor.

14. The angle detector of claim 7, wherein the evaluation unit further generates a composite output signal with the periodicity of the second sensor and the accuracy of the first sensor.

15. The angle detector of claim 7, wherein the evaluation unit is configured to determine whether the second measurement signal exceeds a threshold value, and to add 180 degrees to the first measurement signal when the second measurement signal exceeds said threshold value.

16. The angle detector of claim 7, further comprising a control magnet affixed to the rotatable component such that said control magnet rotates concurrently with said rotatable component, said first and second sensors sensing the rotational position of the control magnet.
